(19) United States
(12) Patent Application Publication
(10) Pub. No.: US 2008/0122107 A1
(43) Pub. Date: May 29, 2008

(54) POLY SILICON HARD MASK

(75) Inventors: Jang-Shiang Tsai, Shindian (TW); Jyu-Horng Shieh, Hsinchu (TW); Ju-Wang Hsu, Taipei City (TW); De-Fang Chen, Lujhu Township (TW); Chia-Hui Lin, (US); Syun-Ming Jang, Hsinchu (TW)

Correspondence Address: DUANE MORRIS LLP;IP DEPARTMENT (TSMC), 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/534,553

(22) Filed: Sep. 22, 2006

(51) Int. Cl. H01L 23/52; H01L 21/311

(52) U.S. Cl. 257/773; 438/700; 257/E21.249; 257/E23.141

(57) ABSTRACT

A method of forming an opening on a low-k dielectric layer using a polysilicon hard mask rather than a metal hard mask as used in prior art. A polysilicon hard mask is formed over a low-k dielectric layer and a photoresist layer is formed over the polysilicon hard mask. The photoresist layer is patterned and the polysilicon hard mask is etched with a gas plasma to create exposed portions of the low-k dielectric layer. The photoresist layer in stripped prior to the etching of the exposed portions of the low-k dielectric layer to avoid damage to the low-k dielectric layer.

### BACKGROUND

The escalating requirements for high-density and performance associated with ultra large-scale integration semiconductor wiring require responsive changes in interconnection technology. Such escalating requirements have been found difficult to satisfy in terms of providing a low RC (resistance capacitance) interconnection pattern, particularly where sub-micron via contacts and trenches have high aspect ratios imposed by miniaturization.

Conventional semiconductor devices typically comprise a semiconductor substrate, normally of doped monocrystalline silicon, and a plurality of sequentially formed dielectric layers and conductive patterns. An integrated circuit is formed containing a plurality of conductive patterns comprising conductive lines separated by inter-wiring spacing. Typically, the conductive patterns on different layers, i.e., upper and lower layers, are electrically connected by a conductive plug filling a via hole, while a conductive plug filling a contact hole establishes electrical contact with an active region on a semiconductor substrate, such as a source/drain region. Conductive lines are formed in trenches which typically extend substantially horizontal with respect to the semiconductor substrate. Semiconductor chips comprising five or more levels of metallization are becoming more prevalent as device geometries shrink to sub-micron levels.

A conductive plug filling a via hole is typically formed by depositing a dielectric interlayer on a conductive layer comprising at least one conductive pattern, forming an opening in the dielectric layer by conventional photolithographic and etching techniques and filling the opening with conductive material, such as tungsten. Excess conductive material on the surface of the dielectric layer is typically removed by chemical mechanical polishing (CMP). One such method is known as damascene and basically involves forming an opening in the dielectric interlayer and filling the opening with a metal. Dual damascene techniques involve forming an opening comprising a lower contact or via hole section in communication with an upper trench section, which opening is filled with conductive material, typically a metal, to simultaneously form a conductive plug and electrical contact with a conductive line.

In efforts to improve the operating performance of a chip, low k dielectric materials have been increasingly investigated for use as replacements for dielectric materials with higher-k values. Lowering the overall k values of the dielectric layers employed in the metal interconnect layers lowers the RC of the chip and improves its performance. However, low k materials such as benzocyclobutene (BCB), hydrogen silsesquioxane (HSQ), SiOF, etc., are often more difficult to handle than traditionally employed higher k materials, such as an oxide. For example, low k dielectric materials are readily damaged by techniques used to remove photoresist materials after the patterning of a layer. Hence, a feature formed in a low k dielectric layer may be damaged when the photoresist mask used to form the feature (e.g., trench or via) is removed.

Other problems that have been observed when working with low k materials are those of via poisoning and resist scumming. For example, via poisoning may be observed after the formation of a via in a low k dielectric layer and the subsequent formation and patterning in the photoresist that forms the trench mask. The via poisoning may cause a mushroom shape of resist to form at the top of the via hole, and resist scum may be seen at the surface of the dielectric layer in the mask opening. An example of this is depicted in FIG. 1. A substrate 10, which may be a conductive material such as copper, is covered by a bottom etch-stop layer 12, which can be made of silicon nitride, for example. The low k dielectric layer 14 has been formed on the bottom etch stop layer 12. A cap layer 16, formed from silicon oxide, for example, covers the low k dielectric layer 14. The via hole 20 was previously formed in the low k dielectric layer 14. Upon deposition and patterning of the photoresist material 18, the mushroom shape 22 is observed due to the via poisoning. It is thought that the photoresist deposition and patterning process produces out gassing from the low k dielectric layer 14 to produce mushroom feature 22 and resist scum 24 within the trench pattern opening 26.

The out gassing prevents the resist from properly getting into the via hole 20 so that it piles up on top of the via hole 20. This out gassing problem leads to improperly formed topology on the wafer. The resist around the via hole 20 becomes very thick and difficult to pattern. When attempts are made to pattern and expose it, that area can not be exposed properly.

Two technical challenges in advanced technology node of 65 nm and beyond are related to the problems associated with low-k dielectrics. One is that 193 nm photoresist is very sensitive to plasma. Insufficient thickness of photoresist for the better profile control is a dilemma between lithographs and etch. The other is the plasma damage caused by strip which leads to the increase of the integrated k-value so as to lose the advantageous effect of using low-k materials instead of oxide for features with a size comparable to the affected region.

Attempts have been made to mitigate the via poisoning and resist scumming problem. One of these is to provide a baking step before the formation of the trench mask layer. Although this has been seen to help the via poisoning problem, it does not substantially eliminate the problem. Other methodology that has been attempted is to provide spin-on organic BARC in the via, but the relatively low adhesion of this material to the via sidewalls and bottom has caused this approach to fail in substantially eliminating via poisoning concerns. Another method to eliminate via poisoning concerns is to provide a thick layer of oxide within the via, but this has the disadvantage of undesirably reducing the via size. Other attempts have included depositions of relatively thick layers of organic and inorganic BARCs within and on top of the via, but such attempts have the undesired effect of requiring a photoresist layer substantially as thick as the BARC layer.

The photoresist masks for forming the via and trench are typically deposited at a thickness of 5000 A or more. Such a thickness is undesirably large, resulting in less accurate patterning than that achievable with a relatively thinner photoresist layer. However, such a large thickness is needed to account for photoresist consumption during patterning and etching and to protect the underlying dielectric layers. The introduction of any additional layers underneath the photoresist masks to allow for reduction of the photoresist layer thickness should not, however, have the undesirable side effects of increasing processing time and costs or increasing the likelihood of damage to underlying layers of materials.

A trilayer approach including photoresist, cap and organic layer provides larger window to prevent the roughening of 193 nm photoresist during patterning. However, low-k damage is still an issue which has not been solved in the prior art. Another method to minimize damage is the use of a metal hard mask. The use of metal hard mask allows shifting the resist strip step from the end of the patterning sequence to before dielectric etch. This not only eliminates the contribution of the strip to the total plasma damage budget, but also the absence of resist on the wafer during the dielectric etch enables the use of a wide range of potentially non damaging cleaning. However, oxide chamber suffers short lifetime because of metal contamination and thus is a fatal issue in terms of production costs.

As noted above there are several disadvantages of the prior art. The photoresist including the tri-layer approach still allows damage in the low-k dielectric and increased photoresist use and cost and requires three layers (photoresist, cap and organic layer) which are costly. The other approach described above is the use of a metal hard mask, which unfortunately as noted above causes contamination of the etch/ash chamber and thus reduces the lifetime of the chamber and creates the extra burden for metal residue removal.

### SUMMARY OF THE INVENTION

The present disclosure provides a solution to the above-stated problems. Thus, in order to obviate the deficiencies in the prior art and to provide an effective process to advantageous use of low-k dielectric, it is an object of the disclosure to provide an improved method of forming an opening on a low-k dielectric layer. In one embodiment, the method includes forming a polysilicon hard mask layer over the low-k dielectric layer and a photoresist layer over the polysilicon hard mask. The photoresist layer can then be patterned and the polysilicon hard masks can be etched with a gas plasma to create exposed portions of the low-k dielectric layer. The photoresist layer can be stripped prior to the etching of the exposed portions of low-k dielectric layer.

It is also an object of the present disclosure to present an improvement for a method of forming an opening on a low-k dielectric layer. In one embodiment, the method includes forming a metal hard mask over the low-k dielectric layer to protect the low-k dielectric layer during photoresist stripping, etching the metal hard mask and stripping the photoresist prior to etching the low-k dielectric layer. The improvement to the method may further include replacing the metal hard mask with a polysilicon hard mask.

It is still another object of the present disclosure to present a method for reducing etching chamber metal contamination during etching of low-k dielectric layer with a hard mask. In one embodiment, the method includes etching the hard mask with a gas plasma to create exposed portions of the low-k dielectric layer, stripping the photoresist layer and etching the exposed portions of low-k dielectric layer. The hard mask can include a polysilicon layer for eliminating metal contamination in the etching chamber.

These and other objects and advantages of the present disclosure will be readily apparent to one skilled in the art form a perusal of the claims, the appended drawings and the following detailed description of the preferred embodiments.

### BRIEF DESCRIPTION OF THE DRAWINGS

FIG. 1 is a cross-section of a metal interconnect portion according to the prior art that exhibits via poisoning and resist scumming after the formation of the structure in accordance with prior art methods.

FIG. 2A-2E are cross-sectional diagrams showing an exemplary method according to an embodiment of the disclosure.

FIG. 3A-3I are cross sectional diagrams showing an exemplary dual damascene process according to one embodiment of the disclosure.

### DETAILED DESCRIPTION

In one embodiment, the disclosure relates to using polysilicon as hard mask in place of, or instead of, the metal hard mask layer. Polysilicon has an etch rate much less than the etch rate of the dielectric layer thereby providing excellent selectivity as the hard mask layer. There is no metal contamination problem with polysilicon which plagues the prior art production methods. The ability and knowledge of patterning polysilicon is well developed. Polysilicon minimizes low-k damage by blocking energetic ions from impinging onto and penetrating into the low-k film perpendicularly and shifts the resist strip step from the end of the patterning sequence to before the dielectric etch step.

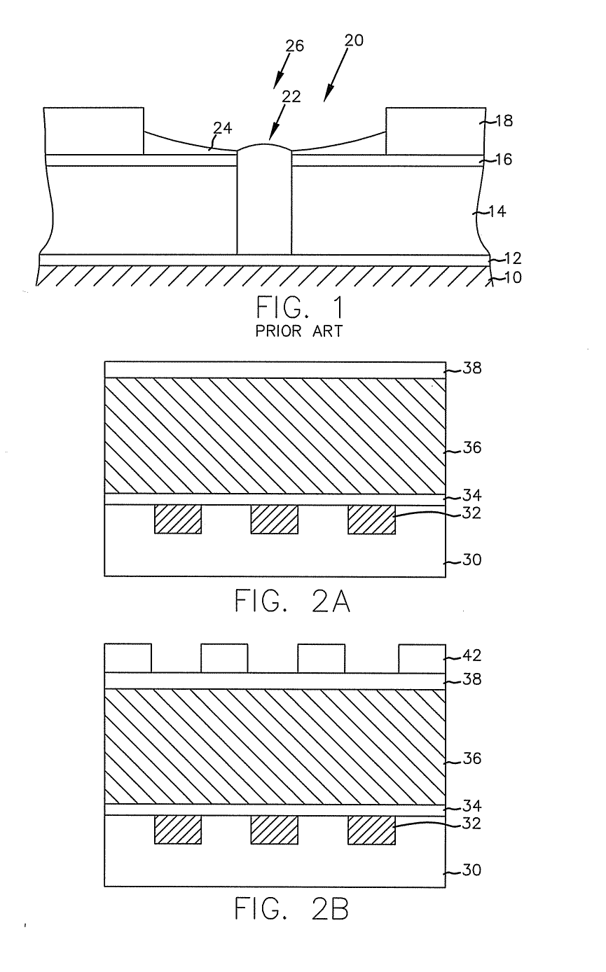

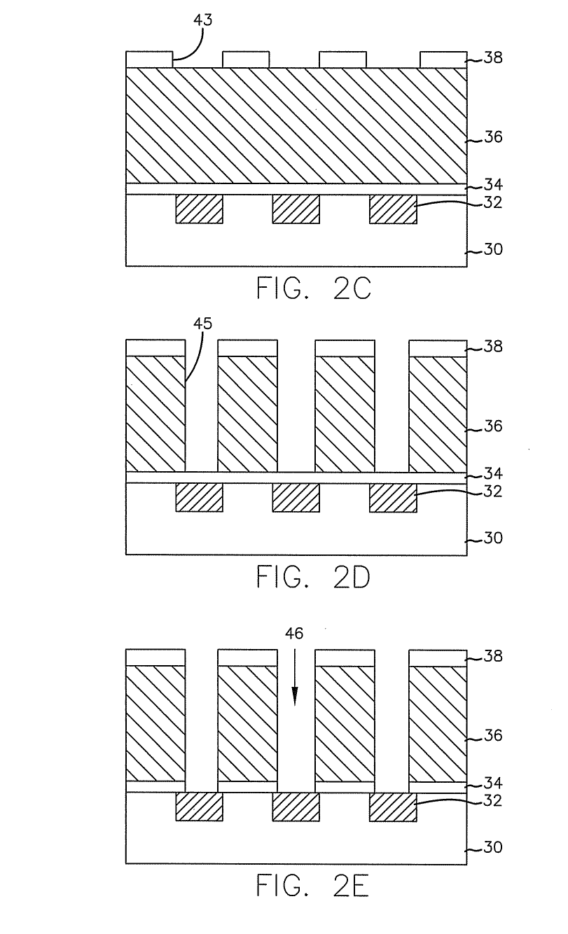

FIGS. 2A to 2E are cross-sectional diagrams showing an exemplary process according to an embodiment of the disclosure. As shown in FIG. 2A, a semiconductor substrate 30 comprises a plurality of metal wire structures 32, a dielectric separation layer 34 covering the metal wire structures 32 and the exposed substrate 30, a low-k dielectric layer 36 with a dielectric constant between 1, 2 and 3 formed on the dielectric separation layer 34. The dielectric separation layer 34 prevents the metal wire structures 32 from oxidizing and prevents the atoms/ions in the metal wire structures 32 from diffusing into the low-k dielectric layer 36. Preferably, the metal wire structure 32 is copper and the dielectric separation layer 34 is silicon nitride or silicon carbide. The low-k dielectric layer 36 is of organic materials, such as spin-on polymer (SOP), FLARE, SILK, PARYLENE and/or PAE-II, and formed through a spin-coating process. Alternatively, the low-k dielectric layer 36 is of Silicon-based materials, such as SiO₂, FSG or USC, and formed through a spin-coating process, or BLACK DIAMOND, CORAL, AURORA, and FLOWFILL, and is formed through a chemical vapor deposition (CVD) or Spin-On-Glass (SOG) processes. In addition, hard mask 38 layer of polysilicon can be formed on the low-k dielectric layer 36. Preferably polysilicon hard mask layer 38 has a thickness less than 600 Å.

As shown in FIGS. 2B and 2C, a first photoresist layer 42 is patterned on the hard mask 38 to define a trench of an opening, and then a plurality of first openings 43 are formed in the hard mask 38 with the first photoresist layer 42 as a mask the openings 41 are formed by among the method gas plasma etching, preferably the gas plasma containing chlorine (cl). Next, the first photoresist layer 42 is removed using preferably gas plasma etching where the gas contains fluorine (fl).

As shown in FIG. 2D, using an etching process with the hard mask 38, a plurality of via holes 45 over the metal wire structures 32 are respectively formed in the low-k dielectric layer 36 with the dielectric separation layer 34 as an etch stop layer. Since the photoresist layer 42 is removed prior to the formation of the via holes 45, the exposed sidewalls of the low-k dielectric layer 36 are not vulnerable to damage by oxygen plasma. As shown in FIG. 2E, the exposed dielectric separation layer 34 is removed. As a result, portions of the metal wire structure 32 are exposed at the bottom of the opening 46.

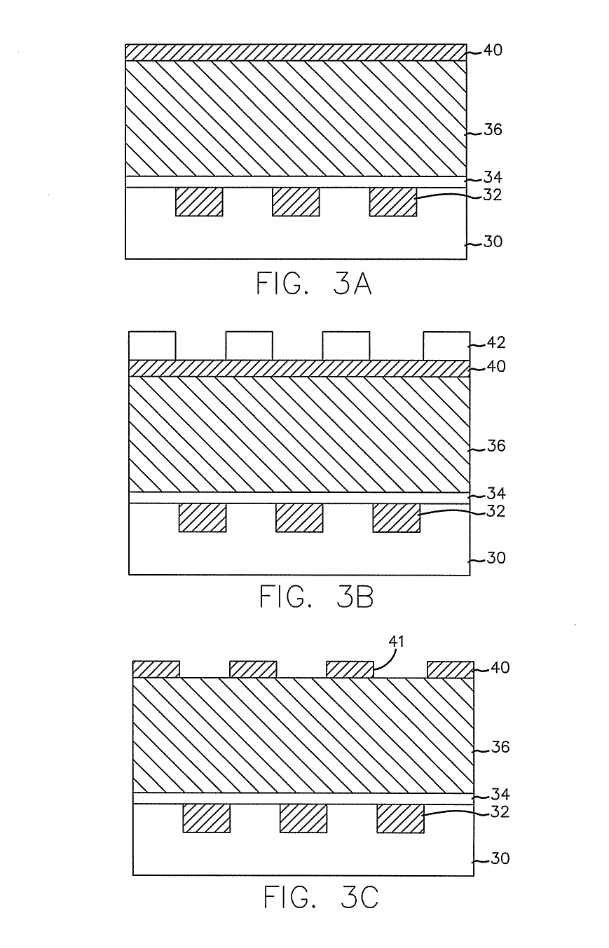

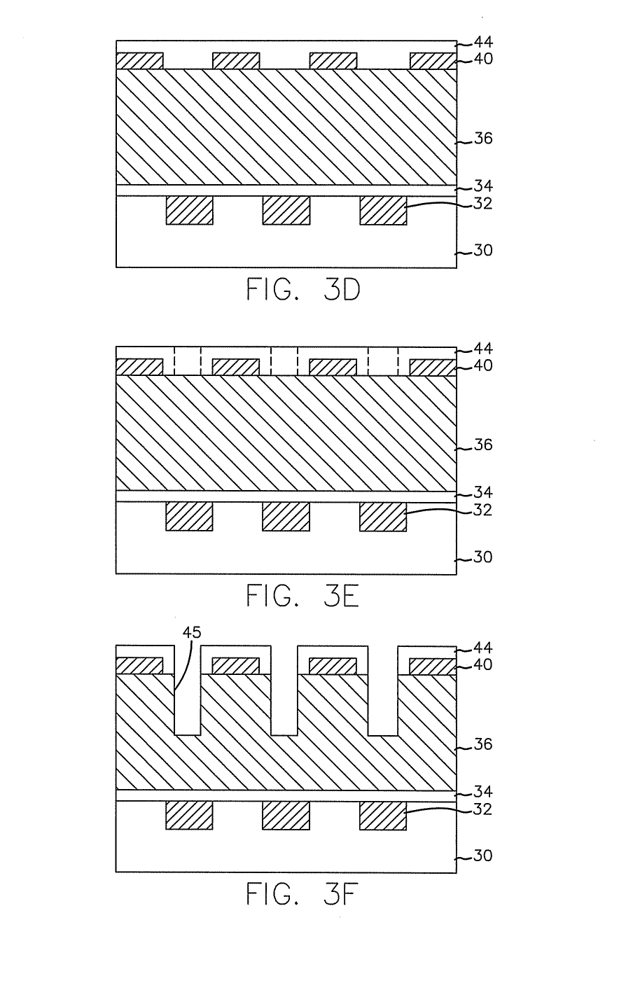

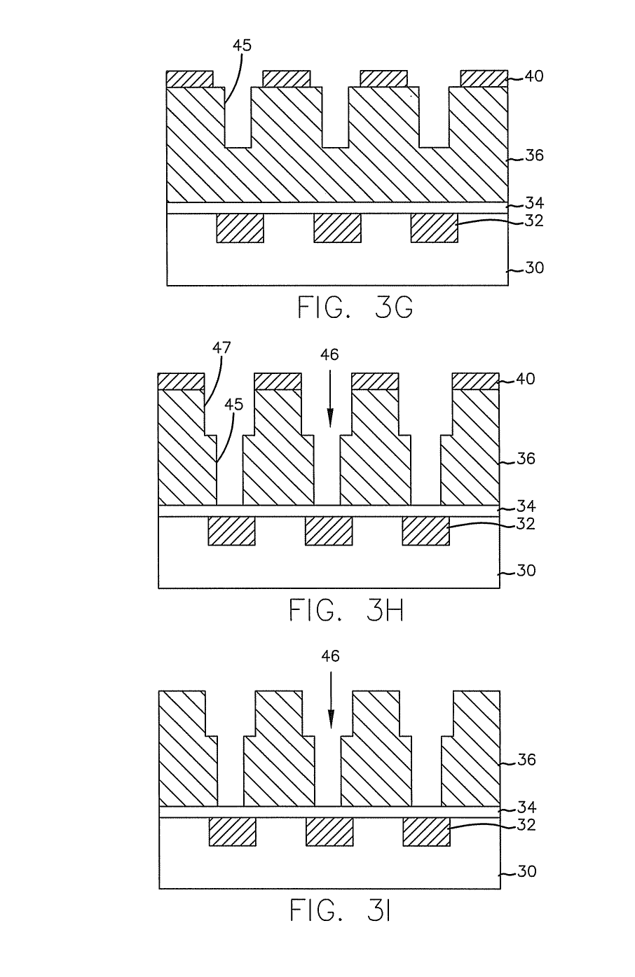

In another embodiment, a dual damascene process using a polysilicon hard mask according to the principles disclosed herein is provided. FIGS. 3A to 3I are cross-sectional diagrams showing a dual damascene process according to an embodiment of the disclosure. As shown in FIG. 3A, the semiconductor substrate 30 has metal wire structures 32, the dielectric separation layer 34, the low-k dielectric layer 36 formed on the dielectric separation layer 34, and the hard mask 40 formed on the low-k dielectric layer 36. The hard mask 40 is a polysilicon material.

As shown in FIGS. 3B and 3C, the first photoresist layer 42 is patterned on the hard mask 40 to define a trench of a dual damascene opening, and then the first openings 41 are formed in the hard mask 40 with the first photoresist layer 42 as a mask. Next, the first photoresist layer 42 is removed. As shown in FIGS. 3D-3E, the second photoresist layer 44 is patterned on the hard mask 40 and the low-k dielectric layer 36 to define a via hole of a dual damascene opening, and then the second openings 45 are formed in the second photoresist layer 44.

As shown in FIG. 3F, using an etching process with the second photoresist layer 44, the via holes 45 over the metal wire structures 32 are respectively formed in the low-k dielectric layer 36. Preferably, the depth of the via hole 45 is larger than half of the height of the low-k dielectric layer 36. Next, as shown in FIG. 3G, the second photoresist layer 44 is removed. Note that since the diameter of the first opening 41 is larger than the diameter of the second opening 43, a part of the low-k dielectric layer 36 surrounding the via hole 45 is exposed.

As shown in FIG. 3H, using etching with the polysilicon hard mask 40, the low-k dielectric layer 36 underlying the via holes 45 is etched to expose the dielectric separation layer 34 over the metal wire structures 32. Meanwhile, the low-k dielectric layer 36 surrounding the via hole 45 is etched to reach a predetermined depth. Thus, trenches 47 passing through the via holes 45 are respectively formed in the low-k dielectric layer 36. The trench 47 and the underlying via hole 45 serve as a dual damascene opening 46. As shown in FIG. 31, the exposed dielectric separation layer 34 and the hard mask 40 are removed. As a result, the metal wire structure 32 is exposed at the bottom of the dual damascene opening 46.

A favorable aspect of the disclosure is the elimination of metal contamination in the etching chamber since a metal hard mask is not used. Another favorable aspect of the disclosed embodiments is that it requires no stripping after forming the dual damascene structures since the photoresist stripping is done prior to dielectric etching, thus resulting in less influence of the stripping on the porous low-k materials of the dielectric. Yet another favorable aspect is that photoresist poisoning is eliminated and, without the large photoresist budget, the lithograph processing for trench patterning is less difficult.

In a method according to an embodiment of the disclosure, the polysilicon layer is deposited using any of the conventional methods such as CVD or sputtering. In an embodiment where CVD is used to deposit the polysilicon layer, a suitable candidate is amorphous Si which enables deposition temperatures below 600° C.

In still another embodiment, the disclosure relates to a method and apparatus for using a polysilicon layer having germanium (Ge) impurities therein. Using Ge impurities is particularly advantageous in that the deposition temperature can be maintained below 400° C. Thus, a dense Si- or Ge-rich layer can be formed on top of the cap pr low-k layer. Thus, using a polysilicon layer having Ge thereon, can reduce the deposition temperature in the CVD process. Another advantage of using polysilicon containing Ge is the deposition of polysilicon with Ge on the sidewalls which can benefit the low-k dielectric layer.

A polysilicon layer having Ge thereon provides a local effect in which hydrogen diffuses from the silicon to the germanium surface phase. Thereafter, the hydrogen is released from the GeH intermediate. Experimental and theoretical reviews show that including Ge in the polysilicon layer can dramatically increase the CVD growth rate at low temperatures. More specifically, hydrogen release from Germanium covered surface is affected by the presence of the impurity which can increase the CVD growth rate.

While the exemplary embodiments of the disclosure have been described, it is to be understood that the embodiments described are illustrative only and that the scope of the subject matter is to be defined solely by the appended claims when accorded a full range of equivalence, many variations and modifications naturally occurring to those of skill in the art from a perusal hereof.

What we claim is:

1. A method of forming an opening on a low-k dielectric layer comprising:
forming a polysilicon hard mask over the low-k dielectric layer;
forming a photoresist layer over the polysilicon hard mask;
patterning the photoresist layer;
etching the polysilicon hard mask with a gas plasma to create exposed portions of the low-k dielectric layer;
stripping the photoresist layer; and,
etching the exposed portions of the low-k dielectric layer.

2. The method of claim 1, wherein the polysilicon hard mask has a thickness of less than 600 A.

3. The method of claim 1, wherein the step of etching the polysilicon hard mask further comprises exposing the polysilicon hard mask to a gas plasma.

4. The method of claim 3, wherein the gas plasma comprises chlorine (cl).

5. The method of claim 1, wherein the step of etching the exposed portions of the low-k dielectric layer further comprises exposing the exposed portions to a gas plasma.

6. The method of claim 5, wherein the gas plasma comprises fluorine (fl).

7. The method of claim 1, wherein the low-k dielectric has a dielectric constant (k) of approximately 1.2-3.0.

8. The method of claim 1, wherein the low-k dielectric further comprises at least one of black diamond, spin on glass (SOG) and carbon-doped silicon oxide.

9. The method of claim 1, wherein the polysilicon layer further comprises germanium.

10. The method of claim 1, wherein the step of forming a polysilicon hard mask over the low-k dielectric layer further comprises forming a polysilicon layer having germanium therein.

11. In a method for forming an opening on a low-k dielectric layer comprising forming a metal hard mask over the low-k dielectric layer to protect the low-k dielectric layer during photoresist stripping, etching the metal hard mask and stripping the photoresist prior to etching the low-k dielectric layer, the improvement comprising replacing the metal hard mask with a polysilicon hard mask.

12. The method of claim 11, wherein the polysilicon hard mask has a thickness of less than 600 A.

13. The method of claim 11, wherein etching the polysilicon hard mask further comprises exposing the polysilicon hard mask to a gas plasma.

14. The method of claim 13, wherein the gas plasma comprises chlorine (cl).

15. The method of claim 13, wherein the step of etching the low-k dielectric layer further comprises exposing the low-k dielectric layer to a gas plasma.

16. The method of claim 15, wherein the gas plasma comprises fluorine (fl).

17. The method of claim 13, wherein the polysilicon hard mask further comprises germanium.

18. A method of reducing etching chamber metal contamination from the etching of a low-k dielectric layer with a hard mask comprising:
etching the hard mask within the etching chamber with gas plasma to create exposed portions of the low-k dielectric layer;
stripping a photoresist layer; and,
etching the exposed portions of the low-k dielectric layer;
wherein the hard mask is a polysilicon material.

19. The method of claim 18, wherein etching the hard mask further comprises exposing the hard mask to gas plasma.

20. The method of claim 19, wherein the gas plasma comprises chlorine (cl).

21. The method of claim 18, wherein the low-k dielectric has a dielectric constant (k) of approximately 1.2-3.0.

22. The method of claim 18, wherein the hard mask layer further comprises germanium.

23. A method for forming a semiconductor structure comprising:
forming a substrate having thereon a plurality of metal wires;
forming a first dielectric layer at least partially covering said substrate and said metal wires;
forming a second dielectric layer at least partially covering said first dielectric layer, the second dielectric layer defining a low-k dielectric layer;
forming a hard mask polysilicon layer on said second dielectric layer, the polysilicon layer further comprising germanium impurities;
forming a photoresist layer on said hard mask layer; and
plasma etching at least one trench in said first and second dielectric layers to expose at least one of the plurality of metal wires.

24. The method of claim 23, wherein the step of forming the hard mask polysilicon layer further comprises chemical vapor deposition of germanium-containing polysilicon at a temperature below 400° C.

25. The method of claim 23, wherein the step of forming the hard mask polysilicon layer further comprises chemical vapor deposition of germanium-containing polysilicon at a temperature below 600° C.

26. A semiconductor structure formed according to the method of claim 23.
